(19) United States
(12) Patent Application Publication
(10) Pub. No.: US 2016/0336313 A1
(43) Pub. Date: Nov. 17, 2016

(54) INTEGRATED CIRCUIT INCLUDING A DIODE AND TRANSISTORS IN A CASCODE CONFIGURATION

(71) Applicant: Semiconductor Components Industries, LLC, Phoenix, AZ (US)

(72) Inventors: Woochul JEON, Phoenix, AZ (US); Chun-Li LIU, Phoenix, AZ (US)

(73) Assignee: Semiconductor Components Industries, LLC, Phoenix, AZ (US)

(21) Appl. No.: 14/713,777

(22) Filed: May 15, 2015

(51) Int. Cl. H01L 27/07; H01L 29/20; H01L 29/423; H01L 29/78; H01L 29/778; H01L 29/861

(52) U.S. Cl. CPC H01L 27/0711; H01L 29/7787; H01L 29/861; H01L 29/42356; H01L 29/78; H01L 29/2003

(57) ABSTRACT

An integrated circuit can include a pair of transistors connected in a cascode configuration. In an embodiment, an anode of a diode can be disposed between the gate electrodes of the transistors. In another embodiment, the transistors can include the transistors and a diode, wherein the anode of the diode is coupled to a current electrode of a transistor; and the cathode is coupled to a current electrode of the other transistor. In a particular embodiment, one of the transistors can be an enhancement mode transistor, and the other transistor can be a depletion mode, high mobility electron transistor.

### FIELD OF THE DISCLOSURE

The present disclosure relates to integrated circuits, and in particular, integrated circuits that include diodes and transistors connected in a cascode configuration.

### RELATED ART

A cascode arrangement can include a high-side transistor, which can be a depletion mode high electron mobility transistor, and a low side transistor, which can be an enhancement mode Si metal-oxide-semiconductor field-effect transistor (MOSFET), that are connected to each other at a middle node. The gate electrode of the high-side transistor is electrically connected to the source of the low-side transistor. The depletion mode, high mobility transistor and the enhancement mode Si MOSFET can be implemented on different dies. Alternatively, such transistors can be implemented on the same die; however, the processing sequence to achieve an integrated circuit can be very complicated.

### BRIEF DESCRIPTION OF THE DRAWINGS

Embodiments are illustrated by way of example and are not limited in the accompanying figures.

FIG. 1 includes illustrations of a circuit drawing of a high electron mobility transistor and a transistor connected in a cascode arrangement with a diode connected in parallel with the high electron mobility transistor, and a cross-sectional view of an embodiment of the circuit when integrated into the same die.

FIG. 2 includes an illustration of a cross-sectional view of a portion of a workpiece after forming a channel layer, a barrier layer, an intermediate layer, and a gate electrode layer over a substrate.

FIG. 3 includes an illustration of a cross-sectional view of the workpiece of FIG. 2 after patterning the gate electrode layer and the intermediate layer and after forming an insulating layer.

FIG. 4 includes an illustration of a cross-sectional view of the workpiece of FIG. 3 after forming source and drain electrodes.

FIG. 5 includes an illustration of a cross-sectional view of the workpiece of FIG. 4 after patterning the insulating layer to form a Schottky contact opening and a gate well.

FIG. 6 includes an illustration of a cross-sectional view of the workpiece of FIG. 5 after forming metallizations.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

The term “heavily doped,” with respect to a dopant concentration of a layer or a region, is intended to mean a dopant concentration sufficient to form an ohmic contact, as opposed to a Schottky contact, with a metal-containing layer, such as a contact plug or an electrode.

The term “integrated circuit” is intended to mean at least two different electronic components formed within or over the same semiconductor substrate.

The term “metal” or any of its variants is intended to refer to a material that includes an element that is within any of the Groups 1 to 12, within Groups 13 to 16, an element that is along and below a line defined by atomic numbers 13 (Al), 31 (Ga), 50 (Sn), 51 (Sb), and 84 (Po). Metal does not include Si or Ge.

The term “semiconductor composition” is intended to mean a composition that has an associated bandgap voltage. For example, p-type doped GaN, n-type doped GaN, and intrinsic GaN have the same semiconductor composition, as GaN, and not the dopants, determine the bandgap energy of the materials. GaN and Al₍₁₋ₓ₎GaₓN, where 0<x<1, having different semiconductor compositions, as they have different bandgap energies.

Group numbers corresponding to columns within the Periodic Table of Elements based on the IUPAC Periodic Table of Elements, version dated Jan. 21, 2011.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

An integrated circuit can include transistors connected in a cascode arrangement and a diode connected in parallel with one of the transistors. In an embodiment, one of the transistors can include a high electron mobility transistor (HEMT). In a particular embodiment, the transistors can include an enhancement mode transistor and a depletion mode HEMT. Both transistors can have channel regions within a III-V semiconductor material, and more particularly, a III-N semiconductor material, such as GaN or Al₍₁₋ₓ₎GaₓN, where 0<x<1. The integration allows for a smaller electronic device to the formed. Furthermore, the relative location of the diode to the gate electrode of the HEMT can allow the HEMT to operate with fewer problems than would otherwise occur if the location of the diode and gate electrode of the HEMT would be reversed.

FIG. 1 includes a circuit diagram of a circuit 10 and a cross-sectional view of an integrated circuit that includes the circuit. Referring to the circuit diagram, the circuit 10 includes transistors 12 and 14 and a diode 16. The transistor 12 can include a High Electron Mobility Transistor (HEMT) that can generate a 2-Dimension Electron Gas (2DEG). The transistor 12 can include a III-V semiconductor material, and in an embodiment, the III-V semiconductor material is a III-N material, and in a more particular embodiment, the III-V semiconductor material is GaN or Al₍₁₋ₓ₎GaₓN, where 0<x<1. The transistor 12 can be a depletion mode transistor. A current electrode of the transistor 12 is coupled to a terminal of the circuit 10, and another electrode of the transistor 12 is coupled to a middle node.

The transistor 14 can include an enhancement mode transistor. A current electrode of the transistor 14 can be coupled to a current electrode of the transistor 12 and the middle node, and another current electrode of the transistor 14 can be coupled to a control electrode of the transistor 12 and another terminal of the circuit 10. In an embodiment, the transistor 14 can be a junction field-effect transistor or an insulated gate field-effect transistor (IGFET).

In an embodiment, transistors 12 and 14 are field-effect transistors. In a particular embodiment, the drain of the transistor 12 is coupled to a drain terminal of the circuit, the source of the transistor 12 is coupled to the middle node and the drain of the transistor 14, the source of the transistor 14 is coupled to the gate of the transistor 12 and to a source terminal of the circuit 10, and the gate of the transistor 14 is coupled to a control terminal, which can also be an input terminal. Thus, the state of the circuit is controlled by controlling the voltage on the control terminal.

The diode 16 may be a Schottky diode or a pn junction diode. The diode 16 can be reversed biased. A cathode of the diode 16 is coupled to the drain of the transistor 14 and the middle node, and an anode of the diode 16 is coupled to the source of the transistor 14 and the source terminal of the circuit 10. In a non-limiting example, the diode 16 can be selected so that the voltage on the gate electrode of the transistor 12 does not get too high. In a particular embodiment, the drain-to-source breakdown voltage for the transistor 12 may be in a range of 30 V to 40 V, and thus, gate electrode of the transistor 12 may reach 30 V to 40 V. In an embodiment, the voltage on the gate electrode may be lowered to 20 V and possibly lower. Further, the effective resistance for the diode 16, which is reversed biased, can be over a 0.1 MΩ. Thus, after reading this specification, skilled artisans will be able to select an effective resistance of the diode 16 to meet the needs or desires for a particular application.

All of the previously described couplings can be in the form of electrical connections between the described components.

FIG. 1 also includes a cross-sectional view of an integrated circuit corresponding to the circuit 10. A brief overview of the integrated circuit is provided. More details regarding the compositions and thicknesses of layers and other features are described later in this specification.

The integrated circuit includes a channel layer 202 and a barrier layer 204. Although not illustrated, one or more layers may be present below the channel layer 202. Such layer can include a base layer that can include a material capable of providing sufficient mechanical support of the overlying layers. Each of the channel layer 202 and the barrier layer 204 can include a III-V semiconductor composition, and in an embodiment, can include a III-N semiconductor composition. In a particular embodiment, the channel layer 202 can include a GaN layer. The barrier layer 204 can include an Al(₁₋ₓ₎GaₓN layer, where 0<x<1.

The transistor 14 can have a transistor structure that includes a gate electrode 224 and an intermediate layer 222. The intermediate layer 222 can be a semiconductor material or a dielectric material. The gate electrode 224 is connected to an input terminal, which can be a control terminal for the circuit 10. In a particular embodiment, the gate electrode is electrically connected to a gate terminal for the circuit 10.

An insulating layer 232 overlies the barrier layer 204 and the gate electrode 224 and includes openings. The insulating layer 232 can include silicon nitride, aluminum nitride, another suitable insulating material, or the like. A source electrode 252 and a drain electrode 258 extend through the insulating layer 252 and barrier 204 and contact the channel layer 202.

A metallization 270 can include a portion 276 that extends through the insulating layer 232 and contacts the barrier layer 204 to form an anode of a Schottky contact (the cathode being on the other side of the contact), and another portion 274 that is a gate electrode for the transistor structure corresponding to the transistor 12 in the circuit 10. The metallization 270 is electrically connected to the source electrode 252 and a source terminal for the circuit 10. A metallization 278 is electrically connected to the drain electrode 258 and the drain terminal for the circuit 10. Other metallization (not illustrated) is electrically connected to the gate electrode 224 and a control (input) terminal for the circuit 10.

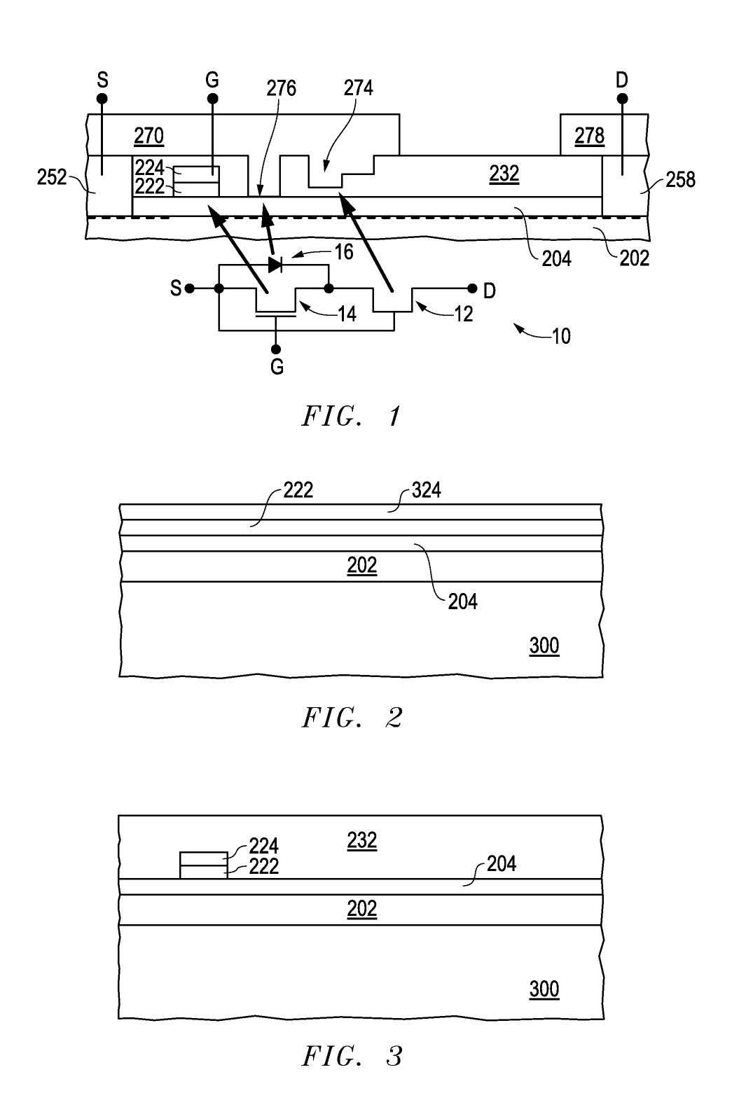

FIG. 2 includes an illustration of a cross sectional view of a portion of workpiece including a substrate 300, the channel layer 202, the barrier layer, the intermediate layer 222, and a gate electrode layer 324. The substrate 300 can allow the channel layer 202 to be epitaxially grown from a base layer. In an embodiment, the substrate 300 can include one of more films of monocrystalline silicon, silicon carbide, aluminum nitride, sapphire, aluminum gallium nitride, gallium nitride, another suitable material, or the like. The thickness is not critical as long as it provides sufficient mechanical support. Generally, the thickness is in a range of 50 microns to 5 mm.

Each of the channel layer 202 and the barrier layer 204 can include a III-V semiconductor composition, and in an embodiment, can include a III-N semiconductor composition. The channel layer 202 and the barrier layer 204 can be monocrystalline.

In a particular embodiment, the channel layer 202 includes a GaN layer. The channel layer 202 can have an n-type conductivity or a p-type conductivity. Exemplary n-type dopants include Si, Ge, O, and the like, and exemplary p-type dopants include Mg, Ca, C, Zn, Be, Cd, and the like. The channel layer 202 may have a dopant concentration of at least 1×10¹² atoms/cm³, at least 5×10¹² atoms/cm³, or at least 1×10¹³ atoms/cm³, and in another embodiment, the dopant concentration may be no greater than 1×10¹⁷ atoms/cm³, no greater ×10¹⁶ atoms/cm³, or no greater 1×10¹⁵ atoms/cm³. In an embodiment, the thickness can be at least 0.11 micron, at least 0.2 micron, or at least 0.3 micron, and in another embodiment, the thickness may be no greater than 2 microns, no greater than 1.2 microns, or no greater than 0.9 microns. In a particular embodiment, the channel layer 202 has a dopant concentration in a range of 1×10¹³ atoms/cm³ to 1×10¹⁵ atoms/cm³, and a thickness in a range of 0.11 micron to 0.9 micron.

The barrier layer 204 can include an Al₍₁₋ₓ₎GaₓN layer, where 0<x<1, where the value for x is selected so that the energy for the conduction band within the barrier layer 204 is sufficiently high enough to confine the 2DEG within the channel layer 202. In an embodiment, x can be at least 0.01, at least 0.05, or at least 0.11, and in another embodiment, x may be no greater than 0.50, no greater than 0.40, or no greater than 0.35. In an embodiment, the thickness of the barrier layer 204 can be at least 2 nm, at least 5 nm, or at 8 nm, and in another embodiment, the thickness may be no greater than 90 nm, no greater than 50 nm, or no greater than 30 nm. In a particular embodiment, the x is in a range of 0.011 to 0.35, and the thickness is in a range of 8 nm to 30 nm.

The intermediate layer 222 can be a semiconductor material or a dielectric material. In an embodiment, the intermediate layer 222 can have a semiconductor composition that is the same as the channel layer 202. In a more particular embodiment when the intermediate layer 222 has a semiconductor composition, the intermediate layer 222 can have a different conductivity type as the channel region 202. The dopant concentration and thickness of intermediate layer can depend on the composition (for example, aluminum content) and thickness of the barrier layer 204. After reading this specification, skilled artisans will be able to determine the dopant concentration and thickness to achieve the proper electrical performance of the depletion mode transistor 12 for their particular needs or desires. The gate electrode layer 324 includes a conductive material and can include one or more conductive films. In an embodiment, the gate electrode layer 324 can include W, doped amorphous or polycrystalline silicon, or the like. The thickness of the gate electrode layer 324 can be in a range of 50 nm to 5000 nm.

A masking layer (not illustrated) is formed over the gate electrode layer 324, and the gate electrode layer 324 and intermediate layer 222 are patterned to form a gate structure, that includes the gate electrode 224 and intermediate layer 222, as illustrated in FIG. 3. The etch chemistry will be tailored to the compositions of the gate electrode layer 324 and the intermediate layer 222. The etch may be performed in a sequence where the gate electrode layer 324 is patterned during one action, and the intermediate layer 222 is patterned during a subsequent action. When patterning the gate electrode layer 324, the etch chemistry can be chosen so that selectivity between the material in the gate electrode layer 324 etches faster than the material in the intermediate layer 222. Similarly, when patterning intermediate layer 22, the etch chemistry can be chosen so that selectivity between the material in the intermediate layer 222 etches faster than the material in the barrier layer 204. The particular etch chemistries can depend on the particular materials of the gate electrode layer 324, the intermediate layer 222, and the barrier layer 204. After knowing the particular materials, skilled artisans will be able to select etch chemistries tailored to their particular application. The etch or each action during the etch sequence can be performed as a timed etch, using endpoint detection, or a combination thereof (endpoint detection with a timed overetch). The masking layer is removed after patterning is complete.

The insulating layer 232 is formed over the gate electrode 224 and the barrier layer 204. Part of the insulating layer will be between the gate electrode of the transistor 12 and the barrier layer 204. In an embodiment, the insulating layer 232 is a single film, and in another embodiment, the insulating layer 232 can include a plurality of films. The film closest to the barrier layer 204 may have a thickness that corresponds to the distance between the bottom of gate electrode of the transistor 12 (see portion 274 in FIG. 1) and the barrier layer 204. Another film may have a different composition and make up all or only a part of a remainder of the insulating layer. For example, still another film may be part of the insulating layer 232 to assist in the formation of the gate well that is subsequently formed. In this matter, each film above the particular film closest to the barrier layer 204 may act as an etch-stop film to a subsequently lower film. Such an embodiment may help to allow for more repeatable depths for different portions of a subsequently-formed gate well.

The insulating layer 232 or the film of the insulating layer 232 that is closer to the barrier layer 204 (as compared to any other film in the insulating layer 232 includes Si₃N₄, AlN or the like. The other film may include the same composition. For example, a stack of Si₃N₄/AlN/Si₃N₄/AlN/Si₃N₄, where the AlN films are relatively thin can allow for most of the insulating layer 232 is Si₃N₄, and the AlN films are present as etch-stop films. In another embodiment, a film of the insulating layer 232 farther from the barrier layer 204 may have a lower dielectric constant, as compared to the film closer to the barrier layer 204. Such a film (farther from the barrier layer 204) may help to reduce capacitive coupling between the drain electrode 258 or metallization 258 to the drain electrode 258 and other parts of the integrated circuit. For example, SiO₂ has a dielectric constant that is about ½ of the dielectric constant of Si₃N₄. Another material having a dielectric constant lower than the dielectric constant of the film closer to the barrier 204 may be selected.

The thickness of the insulating layer 232 is selected to cover the gate electrode 224, so that the subsequently-formed metallization 270 (FIG. 1) does not contact the gate electrode 224. In an embodiment, the insulating layer 232 has a thickness in a range of 100 nm to 3000 nm. Thicknesses of films within the insulating layer 232 will be described with respect to the subsequently formed gate well.

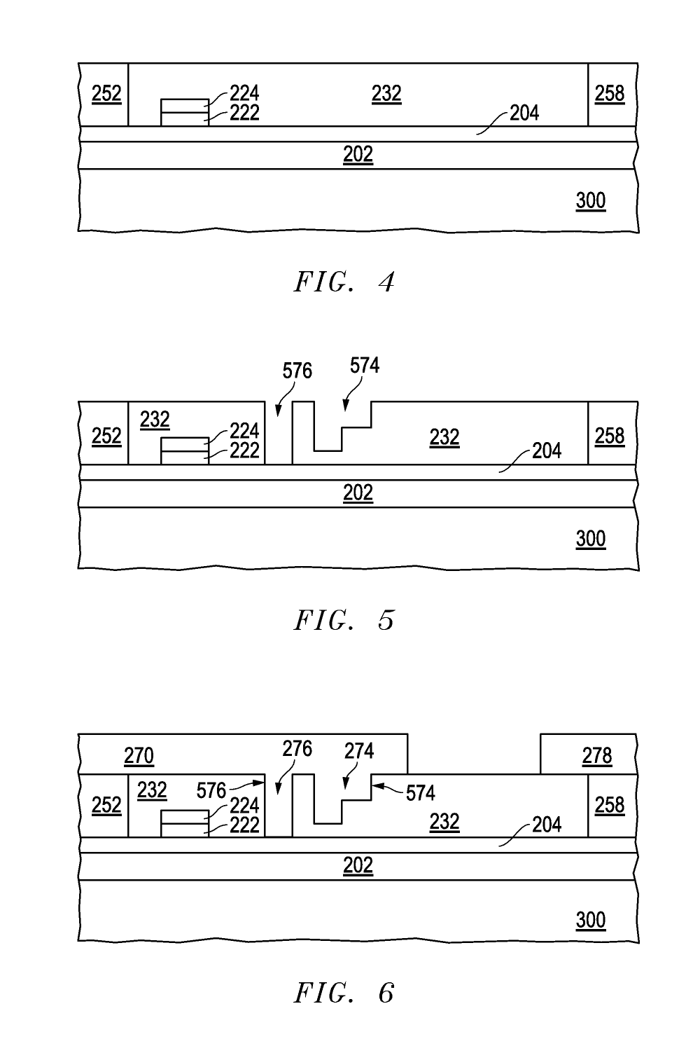

Source and drain electrodes 252 and 258 are formed as illustrated in FIG. 4. A masking layer (not illustrated) is formed over the insulating layer 232 and openings are formed that extend through the insulating layer 232 and the barrier layer 204 at locations where the 252 and 258 will be formed. The openings can be formed using a single step etch or an etch sequence. In a particular embodiment when a sequence is used, an etch chemistry for the material of the insulating layer 232 may be selective to the material in the barrier layer 204. In another particular embodiment, an etch chemistry for the material in the barrier layer 204 may be selective to the material in the channel layer 202. The etch or each action during the etch sequence can be performed as a timed etch, using endpoint detection, or a combination thereof (endpoint detection with a timed overetch). The masking layer is removed after patterning is complete. A dopant may be introduced in the openings to help increase the dopant concentration, if needed, so that ohmic contacts will be formed between the channel layer 202 and each of the source and drain electrodes 252 and 258. The doping may be performed before or after the masking layer is removed.

A conductive layer is formed within the openings and over insulating layer 232, and the portion of the conductive layer over the insulating layer 232 is removed to form the source and drain electrodes 252 and 258. The thickness is sufficient to fill the openings. The conductive layer can be a single conductive film or a plurality of films including a conductive film and may further include an adhesion film, a barrier film, an antireflective film, or any combination thereof. The conductive film can be mostly W, heavily doped amorphous or polycrystalline silicon, or the like, the adhesion film can include Ti, Ta, or the like, the barrier film can include TiN, TaN, TiW, or the like, and the antireflective layer can include TiN. The portion of the conductive layer overlying the insulating layer 232 can be removed by polishing (for example, chemical-mechanical polishing) or an etch back technique.

A masking layer is formed over the source and drain electrodes 252 and 258, and the insulating layer 232 is etched to form a contact opening 576 and a gate well 574, as illustrated in FIG. 5. More than one masking layer may be used in forming the contact opening 576 and gate well 574. For example, the contact opening 576 may be formed with one masking layer, and the gate well 574 can be formed with one or more other masking layers. The contact opening 576 extends completely through the insulating layer 232, and the barrier layer 204 is exposed within the contact opening 576. In an embodiment, the barrier layer 204 is exposed along the bottom of the contact opening 576, as illustrated in FIG. 5.

The gate well 574 includes portions at different depths. The portion that is deeper than any other portion of the gate well 574 corresponds to the location for the gate electrode of the transistor 12. The other portion is shallower as the distance to the drain electrode 578 decreases. Such other portion(s) help to form a shield electrode to reduce the electrical field under the gate area, especially at the drain-side edge of the gate and under the stepped gate field plate. In an embodiment, the shallower portion has depth in a range of 20% to 70% of the thickness of the insulating layer 232, and in a particular embodiment, has a depth in a range of 30% to 60% of the thickness of the insulating layer 232. In another embodiment, the deeper portion has a depth in a range of 40 to 90% of the thickness of the insulating layer 232, and in a particular embodiment, has a depth in a range of 60% to 80% of the thickness of the insulating layer 232. In a further embodiment, the gate well 574 may have more than two portions. The portions of the gate well 574 may become shallower as the distance to the drain electrode 578 decreases.

The use of a plurality of films for the insulating layer 232 can be useful for manufacturing to allow the workpiece-to-workpiece (e.g., wafer-to-wafer) variation to be less than if the insulating layer 232 has a single film. For example, a stack of Si₃N₄/AlN/Si₃N₄/AlN/Si₃N₄, may be beneficial in forming the contact opening 576 and the gate well 574. The thickness of upper Si₃N₄ film or a combined thicknesses of the upper Si₃N₄ film and the upper AlN film may be the depth of the shallower portion of the gate well 574, and the combined thicknesses of the upper Si₃N₄ film, the upper AlN film, and intermediate Si₃N₄ film or the combined thicknesses of the upper Si₃N₄ film, the upper AlN film, intermediate Si₃N₄ film, and lower AlN film may be the depth of the deeper portion of the gate well 574. Each of the AlN films may be no greater than 50%, no greater than 35%, or no greater than 20% of the thickness of each of the Si₃N₄ films. In a particular embodiment, a masking layer be used in forming the portion of the gate well 574 extending upper Si₃N₄ film or a combination of the upper Si₃N₄ film and the upper AlN film, and another masking layer can be used in forming the portion of the gate well extending through a combination of the upper AlN film, the intermediate Si₃N₄ film, and the lower AlN film or a combination of the intermediate Si₃N₄ film and the lower AlN film. After reading this specification, skilled artisans will understand that the embodiments described are merely to illustrate and not to limit the scope of the present invention.

A conductive layer is formed within the Schottky contact opening 576 and the gate well 574 and over the insulating layer 232 and source and drain electrodes 252 and 258, and the conductive layer is patterned to form the metallizations 270 and 278, as illustrated in FIG. 6. The conductive layer can be a single conductive film or a plurality of films including a conductive film and may further include an adhesion film, a barrier film, an antireflective film, or any combination thereof. The conductive film can be mostly Al, Cu, or the like, the adhesion film can include Ti, Ta, or the like, the barrier film can include TiN, TaN, TiW, or the like, and the antireflective layer can include TiN. The thickness of the conductive layer is in a range of 100 nm to 5000 nm. A masking layer is formed over the conductive layer, and a portion of the conductive layer is removed to form the metallizations 270 and 278. The masking layer is removed after forming the metallizations 270 and 278.

The metallization 270 includes a portion within the Schottky contact opening 576. The interface between the metallization 270 and the layer at the bottom of the Schottky contact opening 576 is a Schottky contact and corresponds to the Schottky diode 16 of the circuit 10 (FIG. 1). The metallization 270 is the anode, and the layer on the other side of the metallization 270 within the Schottky contact opening 576 is the cathode. In the embodiment illustrated in FIG. 6, the cathode is the barrier layer 204. The portion of the metallization 270 within the deeper portion of the gate well 574 corresponds to the gate electrode of the transistor 12 in the circuit 10 (FIG. 1). The portion of the metallization 270 within the shallower portion of the gate well 574 and the portion of the metallization 270 that overlies the insulating layer 232 and extends closer to the drain metallization 278 corresponds to the shield electrode. In the embodiment as illustrated, a further portion of the metallization 270 is electrically connected to the source electrode 252 and can be electrically connected to a source terminal for the circuit 10. In the embodiment as illustrated, the metallization 278 is electrically connected to the drain electrode 258 and can be electrically connected to a drain terminal for the circuit 10. Although not illustrated, another metallization is electrically connected to the gate electrode 224 and can be electrically connected to an input or control terminal for the circuit 10. Many other structures can be formed and connected together in parallel to form each of the components as illustrated in FIG. 1.

Other embodiments may be used without deviating from the scope of the teachings as described herein. The source and drain electrodes may be formed after the formation of the Schottky contact opening 576 and gate well 574. The source and drain electrodes 252 and 254 may be replaced by portions of the metallizations 270 and 278. The metallization 270 within the Schottky contact opening 576 and the gate well 574 may be replaced by conductive plugs (similar to the source and drain electrodes 252 and 258 in FIG. 4. After reading this specification, skilled artisans will appreciate that the particular order of formation of the parts of the physical structure can be tailored to the needs or desires for a particular application.

The intermediate layer 222 is not required for the enhancement mode transistor 14. In another embodiment, a recess in the barrier layer 204 can be formed in the gate area. The recess within the barrier layer 204 can help disrupt the 2DEG under the recess. In another embodiment, an implant can be used within the gate area. The implant can be performed using ions from a noble gas, such as Ar⁺. The implant within the channel layer 202 can help disrupt the 2DEG within the channel layer 202.

The integrated circuit has benefits as compared to other designs. The integrated circuit has less thermal mismatch between the transistors 12 and 14 because the transistor structures share the same channel layer 202 and barrier layer 204. The integrated circuit can be easier to package and have less parasitic components. A two die implementation can have lead wires connected to the two die, and such lead wires can introduce parasitic resistance and inductance that can slow the operation of the circuit. When an integrated circuit has both a Si MOSFET and a III-V transistor, such an integrated circuit may still have problems with fabrication and packaging, as such transistors may be formed a substantially different elevations (more than a few microns) between the channel regions of the transistors. The integrated circuit as described herein does not have the wiring, fabrication, or packaging issues as both transistors are formed at the same elevation. The challenges seen with two dies or process integration issues with a Si MOSFET and III-V transistor on the same die are obviated by embodiments as described herein.

The transistor 14 has a gate electrode 224 that can turn on the transistor 14 when the voltage is in a range of approximately 10 V to approximately 20 V. Thus, the gate electrode of the transistor 12 (the portion of the metallization 270 within the gate well 574) does not receive a signal at hundreds of volts, which can lead to current collapse of the transistor 14. Furthermore, the transistor 14 does not have a built-in diode, so the Schottky diode 16 can limit the voltage at the gate electrode of the transistor 12.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the items as listed below.

Item 1. An integrated circuit including a source electrode of a first transistor; a first gate electrode of the first transistor; an anode of a diode; a second gate electrode of a second transistor, wherein the anode is disposed between the first gate electrode and the second gate electrode; and a drain electrode of the second transistor, wherein the source electrode, and anode of the diode, and the second gate electrode are coupled to one another; and a drain of the first transistor and a cathode of the diode are coupled to each other.

Item 2. The integrated circuit of Item 1, further including a channel layer and a barrier layer overlying the channel layer.

Item 3. The integrated circuit of Item 2, wherein the channel layer includes a first III-V semiconductor material; and the barrier layer includes a second III-V semiconductor material that is different from the first III-V semiconductor material.

Item 4. The integrated circuit of Item 3, wherein the first III-V semiconductor material is GaN, and the second III-V semiconductor material is Al₍₁₋ₓ₎GaₓN, wherein 0<x<1.

Item 5. The integrated circuit of Item 2, wherein the source electrode contacts the channel layer; the drain electrode contacts the channel layer; and the anode contacts the barrier layer.

Item 6. The integrated circuit of Item 5, wherein the first gate electrode is spaced apart from the channel layer and the barrier layer.

Item 7. The integrated circuit of Item 6, wherein a semiconductor layer is disposed between the barrier layer and the first gate electrode.

Item 8. The integrated circuit of Item 6, wherein an insulating layer is disposed between the barrier layer and the first gate electrode.

Item 9. The integrated circuit of Item 6, wherein the second gate electrode is spaced apart from the channel layer and the barrier layer.

Item 10. The integrated circuit of Item 1, wherein the second transistor is a high electron mobility transistor.

Item 11. The integrated circuit of Item 10, wherein the first transistor is an enhancement mode transistor, and the second transistor is a depletion mode transistor.

Item 12. The integrated circuit of Item 1, wherein a conductive member includes the anode of the diode and the gate electrode of the second transistor.

Item 13. An integrated circuit including:
a first transistor including a first current electrode, a second current electrode, and a control electrode;
a second transistor including a first current electrode, a second current electrode, and a control electrode, wherein:
   the first current electrode of the second transistor is coupled to the second current electrode of the first transistor; and
   the control electrode of the second transistor is coupled to the first current electrode of the first transistor; and
a diode including an anode and a cathode, wherein:
   the anode is coupled to the first current electrode of the first transistor; and
   the cathode is coupled to the second current electrode of the first transistor.

Item 14. The integrated circuit of Item 13, wherein the diode is disposed between the control electrodes of the first and second transistors.

Item 15. The integrated circuit of Item 13, wherein the first transistor is an enhancement mode transistor, and the second transistor is a depletion mode, high electron mobility transistor.

Item 16. The integrated circuit of Item 13, wherein the first and second transistors further include channel regions within a channel layer.

Item 17. The integrated circuit of Item 16, wherein the first current electrode of the first transistor is a source electrode that contacts the channel layer; the second current electrode of the second transistor is a drain electrode that contacts the channel layer; and each of the control electrodes of the first and second electrodes is a gate electrode that is spaced apart from the channel layer.

Item 18. The integrated circuit of Item 13, wherein a same conductive member is an anode of the diode and the control electrode of the second transistor.

Item 19. The integrated circuit of Item 13, further including a barrier layer overlying the channel layer.

Item 20. An integrated circuit including:
a channel layer including GaN;
a barrier layer including Al₍₁₋ₓ₎GaxN, wherein 0<x<1, and overlying the channel layer;
a source electrode of a first transistor contacting the channel layer;
a gate electrode of the first transistor, wherein the gate electrode layer is spaced apart from the channel layer and the barrier layer;
a conductive member electrically connected to the source electrode and including a first portion and a second portion, wherein:
   the first portion is an anode of a diode and contacts the barrier layer;
   the second portion is a gate electrode of a second transistor and is spaced apart from the channel layer and the barrier layer; and
a drain electrode of the second transistor, wherein the second portion of the conductive member is disposed between the first portion of the conductive member and the drain electrode,
wherein:
   the first transistor is an enhancement mode transistor;
   the second transistor is a depletion mode, high electron mobility transistor; and
   the first transistor and the second transistor are connected in series.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

1. An integrated circuit comprising:
a source electrode of a first transistor;
a barrier layer has an uppermost surface;
an intermediate layer, wherein all of the intermediate layer overlies the uppermost surface of the barrier layer;
a first gate electrode of the first transistor overlying the intermediate layer;
an anode of a diode;
a second gate electrode of a second transistor, wherein the anode is disposed between the first gate electrode and the second gate electrode; and
a drain electrode of the second transistor,
wherein:
the source electrode, and anode of the diode, and the second gate electrode are coupled to one another; and
a drain of the first transistor and a cathode of the diode are coupled to each other.

2. The integrated circuit of claim 1, further comprising a channel layer, wherein the barrier layer overlies the channel layer.

3. The integrated circuit of claim 2, wherein:
the channel layer comprises a first III-V semiconductor material; and
the barrier layer comprises a second III-V semiconductor material that is different from the first III-V semiconductor material.

4. The integrated circuit of claim 3, wherein the first III-V semiconductor material is GaN, and the second III-V semiconductor material is Al₍₁₋ₓ₎GaₓN, wherein 0<x<1.

5. The integrated circuit of claim 2, wherein:
the source electrode contacts the channel layer;
the drain electrode contacts the channel layer; and
the anode contacts the barrier layer.

6. The integrated circuit of claim 5, wherein the first gate electrode is spaced apart from the channel layer and the barrier layer.

7. The integrated circuit of claim 6, wherein a semiconductor layer is disposed between the barrier layer and the first gate electrode.

8. The integrated circuit of claim 6, wherein an insulating layer is disposed between the barrier layer and the first gate electrode.

9. The integrated circuit of claim 6, wherein the second gate electrode is spaced apart from the channel layer and the barrier layer.

10. The integrated circuit of claim 1, wherein the second transistor is a high electron mobility transistor.

11. The integrated circuit of claim 10, wherein the first transistor is an enhancement mode transistor, and the second transistor is a depletion mode transistor.

12. The integrated circuit of claim 1, wherein a conductive member includes the anode of the diode and the gate electrode of the second transistor.

13. An integrated circuit comprising:
a first transistor including a first current electrode, a second current electrode, and a control electrode;
a second transistor including a first current electrode, a second current electrode, and a control electrode, wherein:
the first current electrode of the second transistor is coupled to the second current electrode of the first transistor; and
the control electrode of the second transistor is coupled to the first current electrode of the first transistor; and
a diode including an anode and a cathode, wherein:
the diode is a pn junction diode and has an effective resistance, when reversed biased, of over 0.1 MΩ;
the anode is coupled to the first current electrode of the first transistor; and
the cathode is coupled to the second current electrode of the first transistor.

14. The integrated circuit of claim 13, wherein the diode is disposed between the control electrodes of the first and second transistors.

15. The integrated circuit of claim 13, wherein the first transistor is an enhancement mode transistor, and the second transistor is a depletion mode, high electron mobility transistor.

16. The integrated circuit of claim 13, wherein the first and second transistors further comprise channel regions within a channel layer.

17. The integrated circuit of claim 16, wherein:
the first current electrode of the first transistor is a source electrode that contacts the channel layer;
the second current electrode of the second transistor is a drain electrode that contacts the channel layer; and
each of the control electrodes of the first and second electrodes is a gate electrode that is spaced apart from the channel layer.

18. The integrated circuit of claim 13, wherein a same conductive member is an anode of the diode and the control electrode of the second transistor.

19. The integrated circuit of claim 13, further comprising a barrier layer overlying the channel layer.

20. An integrated circuit comprising:
a channel layer including GaN;
a barrier layer including Al₍₁₋ₓ₎GaxN, wherein 0<x<1, and overlying the channel layer;
a source electrode of a first transistor contacting the channel layer;
a gate electrode of the first transistor, wherein the gate electrode layer is spaced apart from the channel layer and the barrier layer;
and insulating layer;
a first conductive member electrically connected to the source electrode and including a first portion, a second portion, a third portion, and a fourth portion, wherein:
the first portion is an anode of a diode, extends through the insulating layer; and
contacts the barrier layer;
the second portion is a gate electrode of a second transistor and is spaced apart from the channel layer and the barrier layer;
the third portion extends through a part of and not all of the insulating layer;
the fourth portion overlies the insulating layer; and
a combination of the third and fourth portions is a stepped gate field plate that reduces the electrical field under the gate area at the drain-side edge of the gate electrode of the second transistor;
a drain electrode of the second transistor, wherein the second portion of the first conductive member is disposed between the first portion of the conductive member and the drain electrode; and
a second conductive member overlaying the drain electrode and extending over the channel layer, such that the first conductive member is closer to the second conductive member tan to the drain electrode,
wherein:
the first transistor is an enhancement mode transistor;
the second transistor is a depletion mode, high electron mobility transistor; and
the first transistor and the second transistor are connected in series.
